(19) United States
(12) Patent Application Publication
(10) Pub. No.: US 2023/0053083 A1
(43) Pub. Date: Feb. 16, 2023

(54) PLASMA PROCESSING APPARATUS AND FILM FORMING METHOD

(71) Applicant: Tokyo Electron Limited, Tokyo (JP)

(72) Inventors: Hiroyuki MATSUURA, Iwate (JP); Takeshi ANDO, Yamanashi (JP); Takeshi KOBAYASHI, Iwate (JP)

(21) Appl. No.: 17/882,834

(22) Filed: Aug. 8, 2022

(30) Foreign Application Priority Data
Aug. 11, 2021 (JP) 2021-131063

(51) Int. Cl. H01J 37/32; C23C 16/34; C23C 16/509; C23C 16/44

(52) U.S. Cl. CPC H01J 37/32449; H01J 37/32743; H01J 37/32082; H01J 37/32568; H01J 37/32678; H01J 37/32788; C23C 16/345; C23C 16/509; C23C 16/4408; H01J 2237/332; H01J 37/32522

(57) ABSTRACT

A plasma processing apparatus includes: a reaction tube provided in a processing container; a boat that holds a substrate, and is carried into and out from the reaction tube in order to form a film on the substrate; a plasma generation tube that communicates with the reaction tube, and generates plasma from a gas; a gas supply that supplies the gas to the plasma generation tube; electrode installation columns provided to sandwich the plasma generation tube therebetween, and including electrodes, respectively; an RF power supply that is connected to the electrodes, and supplies a radio frequency to the electrodes; a coil provided to be spaced apart from the electrodes in the electrode installation columns; and a DC power supply that is connected to the coil, and supplies a direct current to the coil.

### CROSS-REFERENCE TO RELATED APPLICATIONS

This application is based on and claims priority from Japanese Patent Application No. 2021-131063, filed on Aug. 11, 2021, with the Japan Patent Office, the disclosure of which is incorporated herein in its entirety by reference.

### TECHNICAL FIELD

The present disclosure relates to a plasma processing apparatus and a film forming method.

### BACKGROUND

During a film forming process, a desired film adheres to, for example, the inner wall of a plasma processing apparatus and is deposited thereon. When the cumulative film thickness of the desired film exceeds a preset threshold value, the film is peeled off, and thus, the amount of particles generated on a substrate increases in proportion to the cumulative film thickness.

In order to prevent the amount of particles generated on the substrate from exceeding a control value, the film deposited on the inner wall of the plasma processing apparatus is removed by a dry cleaning, at a timing when the cumulative film thickness reaches a predetermined cumulative film thickness. In order to improve the productivity, the time period from one dry cleaning to the next dry cleaning may be increased, that is, a dry cleaning cycle may be extended as long as possible.

Most of the particles generated on the substrate are caused from a plasma generation portion. As for one of methods for reducing the particles generated on the substrate, for example, Japanese Patent No. 4,607,637 suggests a method of controlling the stress generated in a formed film. However, when the film forming process includes the process of controlling the film stress, the productivity may decrease.

### SUMMARY

According to an aspect of the present disclosure, a plasma processing apparatus includes: a reaction tube provided in a processing container; a boat that holds the substrate, and is carried into and out from the reaction tube in order to form a film on the substrate; a plasma generation tube that communicates with the reaction tube, and generates plasma from a gas; a gas supply that supplies the gas to the plasma generation tube; electrode installation columns provided to sandwich the plasma generation tube therebetween, and including electrodes, respectively; an RF power supply that is connected to the electrodes, and supplies a radio frequency to the electrodes; a coil provided to be spaced apart from the electrodes in the electrode installation columns; and a DC power supply that is connected to the coil, and supplies a direct current to the coil.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a thermal processing apparatus according to an embodiment.

FIG. 2 is a schematic cross-sectional view (cross section taken along a line B-B of FIG. 3) illustrating an example of electrode installation portions according to the embodiment.

FIG. 3 is a view illustrating a cross section taken along a line A-A of FIG. 1.

FIG. 4 is a three-dimensional schematic view of coils according to the embodiment.

FIG. 5 is a predicted view of magnetic fields generated by the coils according to the embodiment.

FIG. 6 is a schematic cross-sectional view illustrating another example of the electrode installation portions according to the embodiment.

FIG. 7 is a flowchart illustrating an example of a film forming method according to an embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In the respective drawings, the same components will be denoted by the same reference numerals, and overlapping descriptions thereof may be omitted.

[Thermal Processing Apparatus]

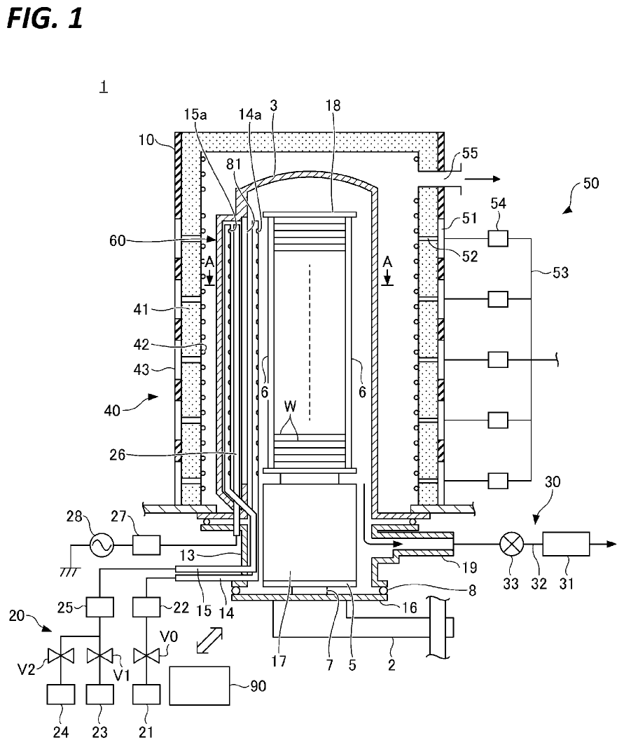

With reference to FIG. 1, a thermal processing apparatus including a plasma generation portion will be described as an example of a plasma processing apparatus according to an embodiment. FIG. 1 is a schematic view illustrating an example of the thermal processing apparatus according to the embodiment.

The thermal processing apparatus 1 includes a processing container 10 and a reaction tube 3. The processing container 10 has a substantially cylindrical shape. The reaction tube 3 is disposed inside the processing container 10. The reaction tube 3 has a substantially cylindrical shape with a ceiling. The reaction tube 3 is formed of, for example, a heat-resistant material such as quartz. The reaction tube 3 accommodates substrates. The thermal processing apparatus 1 has a double structure configured with the reaction tube 3 and the processing container 10.

The thermal processing apparatus 1 includes, for example, a manifold 13, injectors 14 and 15, a lid 16, and a gas outlet 19. The manifold 13 has a substantially cylindrical shape. The manifold 13 supports the lower end of the reaction tube 3. The manifold 13 is formed of, for example, stainless steel.

A boat 18 on which a large number of substrates W (e.g., 25 to 150 substrates) are placed in multiple tiers is inserted (loaded) into the reaction tube 3 from below the manifold 13. In this way, during a film formation, the large number of substrates W are accommodated substantially horizontally at intervals in the vertical direction in the reaction tube 3. The boat 18 is formed of, for example, quartz. The boat 18 has three rods 6 (FIG. 1 illustrates only two rods), and the large number of substrates W are supported by grooves (not illustrated) formed in the rods 6. Each substrate W may be, for example, a semiconductor wafer. After the boat 18 is carried (loaded) into the reaction tube 3, and a desired film is formed on the substrates W, the boat 18 is carried out (unloaded) from the reaction tube 3.

The boat 18 is disposed on a table 5 via a heat insulating cylinder 17 made of quartz. The table 5 is supported on a rotary shaft 7 that penetrates the lid 16 made of a metal (stainless steel) and configured to open/close an opening of the manifold 13 at the lower end thereof.

A magnetic fluid seal is provided at the penetrating portion of the rotary shaft 7 to airtightly seal and rotatably support the rotary shaft 7. A seal member 8 is provided between the peripheral portion of the lid 16 and the lower end of the manifold 13, to maintain the airtightness inside the processing container 10.

The rotary shaft 7 is attached to the tip of an arm 2 supported by a lifting mechanism (not illustrated) such as, for example, a boat elevator. The boat 18 and the lid 16 move up and down in an integrated form, and are inserted into/removed from the processing container 10. The table 5 may be provided to be fixed to the lid 16, so that the substrates W may be processed without rotating the boat 18.

The thermal processing apparatus 1 includes a gas supply unit 20 that supplies a predetermined gas such as a processing gas or a purge gas into the processing container 10. The gas supply unit 20 includes the injectors 14 and 15 which are gas supply pipes. The injectors 14 and 15 are made of, for example, quartz, and penetrate the side wall of the manifold 11 inward to be bent upward and extend vertically. The vertical portions of the injectors 14 and 15 are provided with a plurality of gas holes 14a and a plurality of gas holes 15a, respectively, that are formed at predetermined intervals over the vertical length of the boat 18 corresponding to the substrate support range. Each of the gas holes 14a and 15a discharges a gas in the horizontal direction. The injectors 14 and 15 are made of, for example, quartz, and configured with quartz tubes provided to penetrate the side wall of the manifold 13. While the example of FIG. 1 represents one injector 14 and one injector 15, a plurality of injectors 14 and a plurality of injectors 15 may be provided.

A silicon-containing gas for a film formation is supplied to the injector 14 from a raw material gas supply source 21 through a gas pipe. While the present embodiment describes an example where dichlorosilane (SiH₂Cl₂) is supplied, the silicon-containing gas is not limited thereto. The gas pipe is provided with a flow rate controller 22 and an opening/closing valve V0. Dichlorosilane is output from the raw material gas supply source 21, the flow rate thereof is controlled by the flow rate controller 22, and the supply thereof into the reaction tube 3 is turned ON and OFF by the opening/closing of the opening/closing valve V0.

The vertical portion of the injector 15 is provided inside a plasma generation portion 60. Ammonia gas (NH₃) is supplied to the injector 15 from an ammonia gas supply source 23 through a gas pipe. The gas pipe is provided with a flow rate controller 25 and an opening/closing valve V1. The NH₃ gas is output from the ammonia gas supply source 23, the flow rate thereof is controlled by the flow rate controller 25, and the supply thereof into the plasma generation portion 60 is turned ON and OFF by the opening/closing of the opening/closing valve V1. The NH₃ gas is converted into plasma in the plasma generation portion 60, and is supplied into the reaction tube 3. Further, hydrogen gas (H₂) is supplied to the injector 15 from a hydrogen gas supply source 24 through a gas pipe. The gas pipe is provided with a flow rate controller 25 and an opening/closing valve V2. The H₂ gas is output from the hydrogen gas supply source 24, the flow rate thereof is controlled by the flow rate controller 25, and the supply thereof into the plasma generation portion 60 is turned ON and OFF by the opening/closing of the opening/closing valve V2. The H₂ gas is converted into plasma in the plasma generation portion 60, and is supplied into the reaction tube 3.

Although not illustrated, an injector may be provided to supply a purge gas from a purge gas supply source through a gas pipe. The gas pipe is provided with a flow rate controller and an opening/closing valve. As a result, the purge gas is supplied from the purge gas supply source into the reaction tube 3 at a predetermined flow rate through the gas pipe. As for the purge gas, for example, an inert gas such as nitrogen (N₂) or argon (Ar) may be used. The purge gas may be supplied from at least one of the injectors 14 and 15. In the present embodiment, the purge gas is supplied from the injectors 14 and 15. With this configuration, the gas supply unit 20 supplies ammonia gas, hydrogen gas, and a purge gas into the plasma generation portion 60. Further, the gas supply unit 20 supplies dichlorosilane and a purge gas into the reaction tube 3. The processing gas includes, for example, a film formation gas, a cleaning gas, and a purge gas. In the present embodiment, the film formation gas is used for forming a silicon nitride (SiN) film, and includes a silicon-containing gas such as dichlorosilane, ammonia gas, and hydrogen gas.

The thermal processing apparatus 1 further includes, for example, an exhaust unit 30, a heating unit 40, a cooling unit 50, and a control device 90. The processing gas supplied into the processing container 10 is exhausted by the exhaust unit 30 through the gas outlet 19. The gas outlet 19 is formed in the manifold 13. The exhaust unit 30 includes an exhaust device 31, an exhaust pipe 32, and a pressure controller 33. The exhaust device 31 is, for example, a vacuum pump such as a dry pump or a turbo molecular pump. The exhaust pipe 32 connects the gas outlet 19, the pressure controller 33, and the exhaust device 31. The pressure controller 33 is provided in the middle of the exhaust pipe 32, and adjusts the conductance of the exhaust pipe 32, thereby controlling the pressure in the processing container 10. The pressure controller 33 is, for example, an automatic pressure control valve.

The heating unit 40 includes a heat insulating material 41, a heater 42, and an outer skin 43. The heat insulating material 41 has a substantially cylindrical shape, and is provided around the reaction tube 3. The heat insulating material 41 is mainly formed of silica and alumina. The heater 42 is an example of a heating element, and is provided on the inner circumference of the heat insulating material 41. The heater 42 is provided in a linear or planar shape on the side wall of the processing container 10, so that a temperature control may be performed for a plurality of zones obtained by dividing the processing container 10 in the height direction. The outer skin 43 is provided to cover the outer periphery of the heat insulating material 41. The outer skin 43 reinforces the heat insulating material 41 while maintaining the shape of the heat insulating material 41. The outer skin 43 is formed of a metal such as stainless steel. In order to suppress the influence of the heat of the heating unit 40 on the outside, a cooling jacket (not illustrated) may be provided on the outer periphery of the outer skin 43. In the heating unit 40, a heat generation value of the heater 42 is determined by a power supplied to the heater 42, and as a result, the heating is performed until the temperature inside the processing container 10 reaches a desired temperature.

The cooling unit 50 supplies a cooling fluid toward the processing container 10, to cool the wafers W inside the processing container 10. The cooling fluid may be, for example, air. The cooling unit 50 supplies the cooling fluid toward the processing container 10, for example, when the temperature of the wafers W needs to be rapidly dropped after a thermal processing. The cooling unit 50 includes a fluid flow path 51, an injection hole 52, a distribution flow path 53, a flow rate regulator 54, and a heat exhaust port 55.

A plurality of fluid flow paths 51 is formed in the height direction between the heat insulating material 41 and the outer skin 43. For example, each fluid flow path 51 is formed on the external side of the heat insulating material 41 along the circumferential direction thereof. The injection hole 52 is formed to penetrate the heat insulating material 41 from each fluid flow path 51, and injects the cooling fluid into the space between the reaction tube 3 and the heat insulating material 41.

The distribution flow path 53 is provided outside the outer skin 43, and distributes and supplies the cooling fluid to each fluid flow path 51. The flow rate regulator 54 is provided in the middle of the distribution flow path 53, and regulates the flow rate of the cooling fluid supplied to the fluid flow path 51.

The heat exhaust port 55 is provided above a plurality of injection holes 52, and discharges the cooling fluid supplied into the space between the reaction tube 3 and the heat insulating material 41, to the outside of the thermal processing apparatus 1. The cooling fluid discharged to the outside of the thermal processing apparatus 1 is cooled by, for example, a heat exchanger, and is supplied again to the distribution flow path 53. The cooling fluid discharged to the outside of the thermal processing apparatus 1 may not be reused.

The control device 90 controls the operation of the thermal processing apparatus 1. The control device 90 may be, for example, a computer. A storage medium stores a computer program for performing the entire operation of the thermal processing apparatus 1. The storage medium may be, for example, a flexible disk, a compact disk, a hard disk, a flash memory, or a DVD.

[Plasma Generation Portion and Electrode Installation Portions]

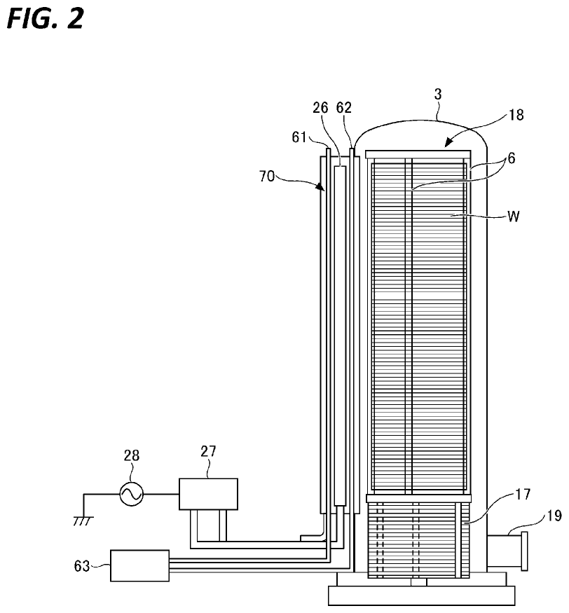

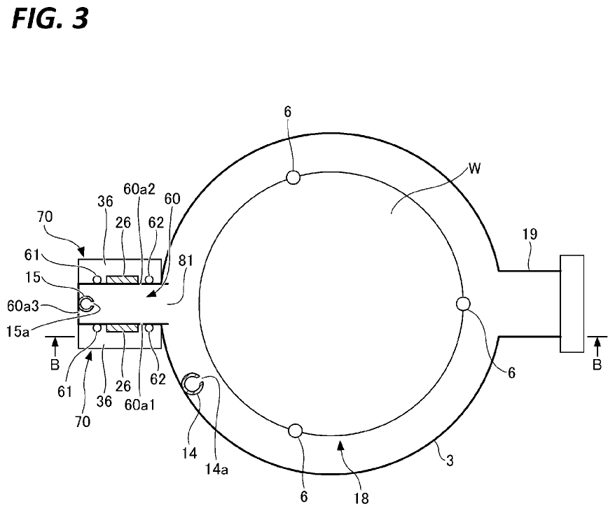

The plasma generation portion 60 is provided on a portion of the side wall of the reaction tube 3. The plasma generation portion 60 communicates with the reaction tube 3 through an opening 81 formed in the reaction tube 3. An example of the configuration of the plasma generation portion 60 and electrode installation portions will be described with reference to FIGS. 2 and 3, in addition to FIG. 1. FIG. 2 is a schematic cross-sectional view illustrating an example of electrode installation portions 70 according to the embodiment, and illustrates the cross section taken along a line B-B of FIG. 3, a matching circuit 27, an RF power supply 28, and a DC power supply 63. FIG. 3 is a view illustrating the cross section taken along a line A-A of FIG. 1.

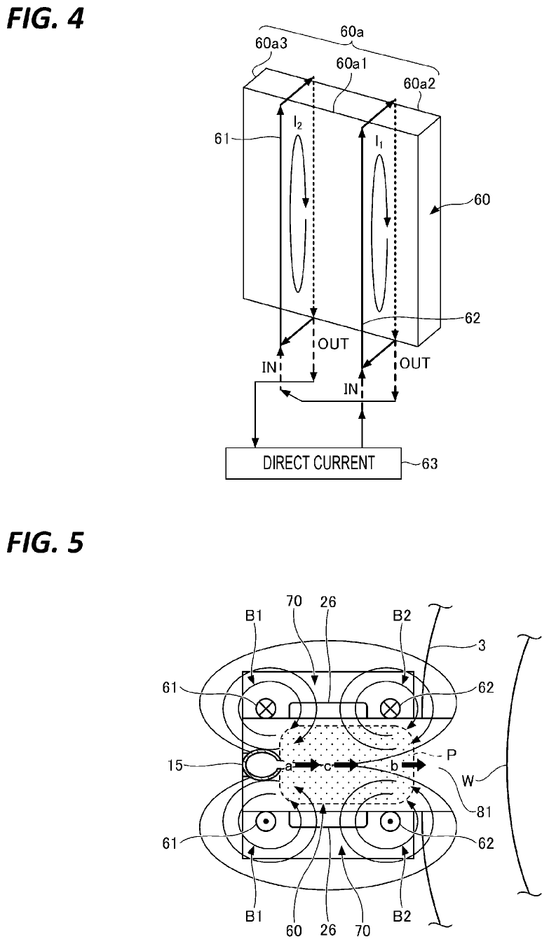

As illustrated in FIGS. 1 to 3, the plasma generation portion 60 is provided on a portion of the side wall of the reaction tube 3 along the longitudinal (vertical) direction of the reaction tube 3, and generates plasma from a gas. Referring to FIG. 3, the plasma generation portion 60 has a plasma partition wall 60a (see, e.g., FIG. 4) that protrudes from the reaction tube 3 in a rectangular shape along the longitudinal direction of the reaction tube 3. The plasma partition wall 60a is welded to the reaction tube 3, and the internal space of the plasma generation portion 60 communicates with the reaction tube 3 through the opening 81 (see, e.g., FIGS. 1 and 3).

As illustrated in FIG. 3, the injector 14 is provided inside the reaction tube 3 to supply a silicon precursor (e.g., dichlorosilane SiH₂Cl₂). The raw material gas supply source 21 of the gas supply unit 20 supplies dichlorosilane gas into the reaction tube 3 from the plurality of gas holes 14a formed in the vertical direction.

The injector 15 is provided inside the plasma generation portion 60 to supply the NH₃ gas and the H₂ gas. The ammonia gas supply source 23 of the gas supply unit 20 supplies the NH₃ gas into the plasma generation portion 60 from the plurality of gas holes 15a formed in the vertical direction, and the hydrogen gas supply source 24 supplies the H₂ gas into the plasma generation portion 60 from the plurality of gas holes 15a formed in the vertical direction.

The gas outlet 19 (see FIGS. 1 and 3) is provided in the lower portion of the side wall of the reaction tube 3 that faces the opening 81, to evacuate the inside of the reaction tube 3, and exhausts the gas supplied from the injectors 14 and 15.

As illustrated in FIG. 3, the electrode installation portions 70 are provided to sandwich the plasma generation portion 60 therebetween, and include radio-frequency electrodes 26 and coils 61 and 62 therein. The electrode installation portions 70 are provided adjacent to the facing plasma partition walls 60a1 and 60a2 of the plasma partition wall 60a of the plasma generation portion 60. Two radio-frequency electrodes 26 make a pair, and are provided on both walls 60a1 and 60a2 of the plasma generation portion 60 such that the plasma generation portion 60 is interposed between the radio-frequency electrodes 26. The plasma generation portion 60 is a vacuum space, and the electrode installation portions 70 are atmospheric spaces.

FIG. 2 illustrates the radio-frequency electrode 26 and the coils 61 and 62 provided in the electrode installation portion 70 on one side of the plasma generation portion 60. As illustrated in FIG. 2, the radio-frequency electrode 26 extends longitudinally along one of the facing plasma partition walls 60a1 and 60a2 (hereinafter, also referred to as the walls 60a1 and 60a2). The radio-frequency electrode 26 is paired with the radio-frequency electrode 26 that extends longitudinally along the other of the walls 60a1 and 60a2 in the electrode installation portion 70 on the other side of the plasma generation portion 60. The coils 61 and 62 are wound along the walls 60a1 and 60a2 (see, e.g., FIG. 4).

The pair of radio-frequency electrodes 26 are connected to the RF power supply 28 via the matching circuit 27, and a radio frequency (RF) is supplied from the RF power supply 28. The plasma generation portion 60 converts the NH₃ gas into plasma with a radio-frequency power, to generate an active species for nitriding a film in the plasma generation portion 60. Further, the plasma generation portion 60 converts the H₂ gas into plasma with a radio-frequency power, to generate hydrogen (H) radicals in the plasma generation portion 60.

The coils 61 and 62 are provided to be spaced apart from the radio-frequency electrode 26. As illustrated in FIG. 2, the coils 61 and 62 are connected to the DC power supply 63. The DC power supply 63 supplies a direct current to the coils 61 and 62.

As illustrated in FIG. 3, an insulating member 36 such as quartz is embedded in the electrode installation portions 70, and electrically insulates the pair of radio-frequency electrodes 26 and the coils 61 and 62 that are provided along the facing walls 60a1 and 60a2 of the plasma partition wall 60a.

The coils 61 and 62 are wound one or more along the facing walls 60a1 and 60a2. FIG. 4 is a three-dimensional schematic view of the coils 61 and 62 for applying magnetic fields. The two coils 61 and 62 are wound around the external side of the plasma generation portion 60. The coil 61 is relatively farther away from the reaction tube 3, and the coil 62 is relatively closer to the reaction tube 3. As illustrated in FIG. 4, the coils 61 and 62 are connected to each other below the plasma generation portion 60, to form an integrated coil as a whole. The DC power supply 63 is connected to the coils, and supplies a direct current to the coils. Further, a radio frequency is applied from the RF power supply 28 to the radio-frequency electrodes 26. As a result, magnetic fields are applied to the inside of the plasma generation portion 60 that generates plasma. The coils 61 and 62 may be separated from each other, and may be connected to dedicated DC power supplies, respectively. While FIG. 4 represents the coils 61 and 62 wound once along the walls 60a1 and 60a2, the coils 61 and 62 may be wound multiple times.

FIG. 5 illustrates a predicted view of the magnetic fields generated by the coils 61 and 62 according to the embodiment. By increasing the plasma density in the plasma generation portion 60, and increasing the production amount of required reaction active species, the time for a plasma processing step during a film formation may be reduced. Thus, in the present embodiment, the coils 61 and 62 are provided near the radio-frequency electrodes 26 (parallel plate electrodes), in order to increase the plasma density and increase the production amount of reaction active species. Then, a direct current is supplied to the coils 61 and 62 to generate magnetic fields. Then, the generated magnetic fields are caused to act on the plasma generated from the NH₃ gas and the H₂ gas by the radio frequency.

The magnetic fields formed by the two coils 61 and 62 have the directions and the ranges of the magnetic fields indicated by arrows in FIG. 5. In the examples of FIGS. 4 and 5, the direct current flows through the front coils 61 and 62 from the bottom to the top, flows backward at the top, and flows through the rear coils 61 and 62 from the top to the bottom. As a result, the magnetic fields illustrated in FIG. 5 are generated. The direction of the direct current may be reversed. Electrons in plasma P perform a circular motion (cyclotron motion) due to the influence of the magnetic fields. Accordingly, it is possible to increase the number of times that the electrons collide with neutral particles in the plasma P (collision frequency). Thus, in the present embodiment in which the magnetic fields are formed even though the radio frequency of the same power is supplied to the radio-frequency electrodes 26, the density of the plasma P may be increased, as compared with a case where no magnetic field is formed.

Points “a,” “b,” and “c” illustrated in FIG. 5 are located at the center of the plasma generation portion 60 (at a substantially equal distance from the walls 60a1 and 60a2). The point “a” is located close to the injector 15 relative to the region directly below the radio-frequency electrodes 26, is also located in the middle of the line that connects the front and rear coils 61 illustrated in FIG. 5, and is affected by the magnetic fields generated by the coils 61. The point “b” is located close to the reaction tube 3 relative to the region directly below the radio-frequency electrodes 26, is also located in the middle of the line that connects the front and rear coils 62, and is affected by the magnetic fields generated by the coils 62. The point “c” is located in the region directly below the radio-frequency electrodes 26, that is, at the center between the radio-frequency electrodes 26. At the point “c,” a combined magnetic field formed by the coils 61 and 62 is generated toward the injector 15 from the side of the substrates W. Since the magnetic field at the point “c” is smaller than the magnetic field at the point “a” or “b,” the effect of the application of magnetic fields is relatively small at the point “c.”

The coils 61 and 62, or only the coil 62 is provided, and the magnetic fields generated by causing the direct current to flow through the coils are applied to plasma, so as to increase the plasma density. The number of winding times of each coil is about 1 to about 10. The direct current supplied to the coils is about 1 A to about 10 A. Only one of the coils 61 and 62 may be provided. When any one of the coils 61 and 62 is provided, the coil 62 relatively close to the substrates W may be provided, rather than the coil 61 relatively farther away from the substrates W.

Since the coils 61 and 62 are provided inside the processing container 10 in which the heater 42 is disposed, a metal material having a relatively high heat resistance and a relatively high conductivity is used for the coils. When the material having a relatively high conductivity is used, a relatively large magnetic field may be generated.

Electrons (mass “mₑ” and charge “e”) in a magnetic field of a magnetic flux density B perform the circular (cyclotron) motion at a constant angular velocity (angular frequency) ωₑ=eB/mₑ within the plane perpendicular to the magnetic field. The ωₑ is called a cyclotron frequency, and electromagnetic waves with the angular frequency equal to the cyclotron frequency are subjected to a resonance absorption. This phenomenon is called an electron cyclotron resonance (ECR).

When the cyclotron frequency ωₑ is equal to a radio frequency “ω,” the velocity of the electrons is directly proportional to time, and the electrons are accelerated with time. Since the electrons continue to absorb energy due to the electric fields generated by the radio-frequency electrodes, this condition corresponds to the electron cyclotron resonance.

For example, when the frequency of the plasma generation radio frequency output from the RF power supply 28 is 13.56 MHz, the cyclotron frequency of the electrons in the plasma at the point “b” is ωₑ [rad/s]. The magnetic flux density at which ω_{c}/2π=fₑ [s⁻¹] is equal to 13.56 MHz that is the frequency of the RF power supply 28 is 0.48 mT. In order to provide only the coil 62, and set the magnetic flux density at the point “b” to 0.48 mT, the number of winding times of the coil 62 needs to be 5, and the current of about 5 A needs to be supplied.

The current caused to flow through the coils 61 and 62 may be arbitrarily set in the range of 0 A to 10 A by the control device 90, so that an appropriate magnetic field may be applied according to conditions for the plasma generation. The magnitude of the current of the coils 61 and 62 may be set as one of process parameters which may be set within a film forming recipe used for the film forming method of the present embodiment.

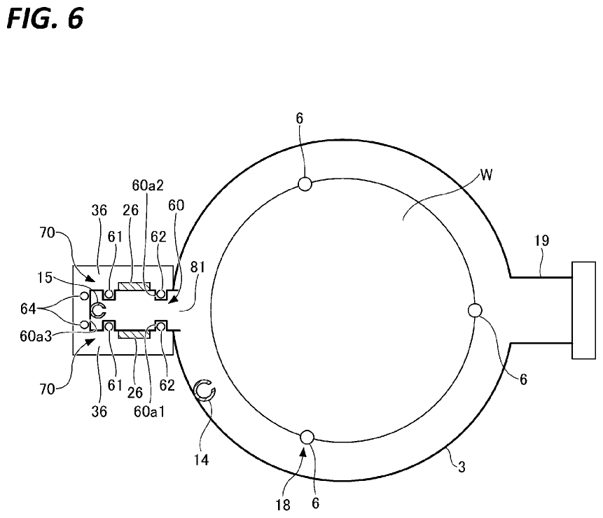

One or more coils are provided inside the electrode installation portions 70, and a maximum of two coils may be provided therein. Without being limited thereto, the coils may be attached to the external side of the plasma generation portion 60 along the wall 60a3 of the plasma partition wall 60a to which the injector 15 is provided adjacent. FIG. 6 illustrates an example where a coil 64 is provided on the external side of the plasma generation portion 60 along the wall 60a3. In this case, the three coils 61, 62, and 64 may be provided, or at least one of the coils 61, 62, and 64 may be provided.

In the present embodiment, as illustrated in FIG. 4, the coils 61 and 62 are wound around once and arranged side by side. Without being limited thereto, each of the coils 61 and 62 may be divided into two upper and lower coils, and the upper coils 61 and 62 and the lower coils 61 and 62 may be provided separately.

Preferably, the plasma density may be highest at the position of the center of the plasma generation portion 60 that the RF power supply 28 faces. Thus, as illustrated in FIG. 6, recesses may be provided in each of the walls 60a1 and 60a2 of the plasma generation portion 60 in the vicinity of both sides of the radio-frequency electrode 26, and the coils 61 and 62 may be disposed in the recesses. As a result, the coils 61 and 62 may be provided further closer to the position of the center of the plasma generation portion 60 that the RF power supply 28 faces. Thus, strong magnetic fields may be formed near the center of the plasma generation portion 60, so that the plasma density may be further increased.

[Film Forming Method]

Descriptions will be made on a method of forming a film by carrying the substrates W into the above-described thermal processing apparatus 1 which is a batch-type plasma processing apparatus. In the present embodiment, a step of forming a silicon nitride film (hereinafter, referred to as an “SiN film”) is performed by an atomic layer deposition (ALD) method. The film forming method is not limited to the ALD method. For example, a CVD method may be applied to the film formation.

When the cumulative film thickness of the SiN film deposited on, for example, the inner wall of the processing container 10 of the thermal processing apparatus 1 exceeds a preset threshold value during the film forming step, the SiN film is peeled off, and the amount of particles generated on the substrates increases in proportion to the cumulative film thickness. For example, when the inside of the reaction tube 3 is maintained at 500° C. to 600° C., and the SiN film is formed by the ALD method using plasma, the increasing amount of particles may exceed a control value around the cumulative film thickness of 1.0 μm.

In order to prevent the amount of particles generated on the substrates from exceeding the control value, the SiN film formed on the inner wall of the processing container 10 of the thermal processing apparatus 1 is removed by a dry cleaning, at the timing when the cumulative film thickness reaches a predetermined cumulative film thickness. Then, the step of forming the SiN film by the ALD method is repeated until the cumulative film thickness reaches the predetermined cumulative film thickness again. The time period from the dry cleaning of the processing container 10 to the next dry cleaning will be referred to as a “dry cleaning cycle,” and the length of the time period is usually expressed by the cumulative film thickness (μm). In recent years, the extension of the dry cleaning cycle has been one of important issues for improving the operation rate of the thermal processing apparatus 1.

When the SiN film is formed by the ALD method in the thermal processing apparatus 1, the particles generated on the substrates are mainly caused from the plasma generation portion 60 provided near the substrates. It is believed that a portion of the SiN film formed in the plasma generation portion 60 is peeled off by the action of plasma, and adheres to the surfaces of the substrates W as minute particles.

Among several methods for reducing the particles generated on the substrates W, one of effective methods is a method of controlling the stress occurring in the formed SiN film. In this case, in order to control the stress occurring in the SiN film, a hydrogen radical purge (HRP) step is added during the ALD sequence (ALD cycle).

However, when the HRP step is added, the time for the ALD cycle increases, which lowers the productivity. In order to achieve both the improvement of productivity and the control of film stress, in other words, in order to maintain and improve the effect of the HRP while reducing the time for the ALD cycle, the film formation may be performed using the thermal processing apparatus 1 capable of increasing the plasma density and increasing the production amount of required reaction active species.

The ALD cycle for the SiN film using the thermal processing apparatus 1 repeats the following steps: (1) nitriding ammonia gas by plasma using a plasma assist, (2) vacuum purge, (3) flow of a silicon precursor, (4) vacuum purge, and (5) the HRP, in this order. As an example of (3) the flow of a silicon precursor, for example, dichlorosilane gas is caused to flow in the reaction tube 3 to cause a thermal reaction. The step (3) does not use plasma.

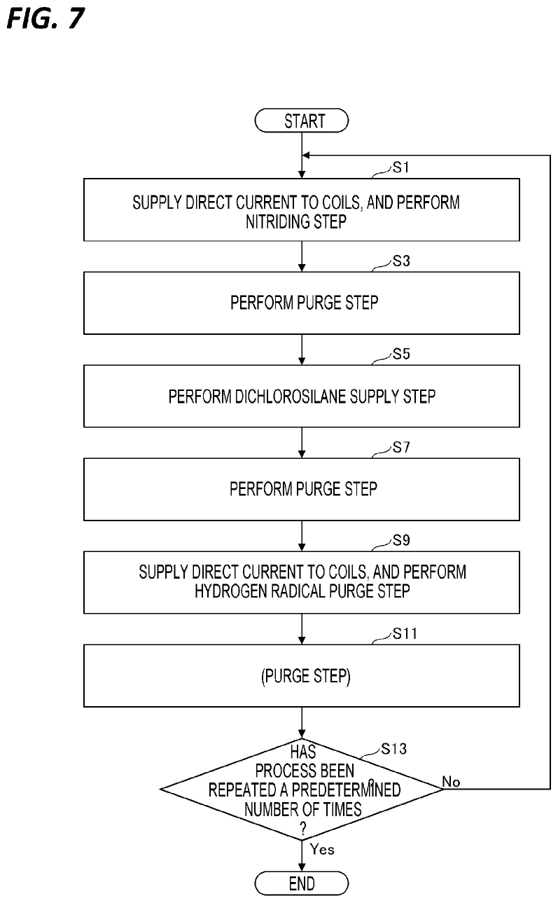

In order to improve the productivity, it is effective to reduce the time for the steps (1) and (5) using plasma. To this end, the plasma density in the plasma generation portion 60 is increased, and the production amount of required reaction active species is increased. It is known that when the radio-frequency power to be applied is simply increased to improve the production amount of required reaction active species, the generation amount of particles increases in proportion thereto. Accordingly, in the thermal processing apparatus 1 of the present embodiment, the improvement of productivity is achieved by applying the DC magnetic fields to the generated capacitively coupled plasma P, instead of increasing the radio-frequency power. Hereinafter, the film forming method according to the present embodiment will be described with reference to FIG. 7. FIG. 7 is a flowchart illustrating an example of the film forming method according to the embodiment. The control device 90 controls the film forming method of FIG. 7.

When the process is started, the control device 90 supplies the direct current to the coils 61 and 62, to generate the magnetic fields in the plasma generation portion 60. Further, the NH₃ gas is supplied from the injector 15, and the radio-frequency power is applied to the radio-frequency electrodes 26. As a result, plasma is generated from the NH₃ gas by the radio-frequency power. In the reaction tube 3, the substrates W are exposed to the plasma of the NH₃ gas sent from the plasma generation portion 60, and the nitriding step is performed for nitriding the film on the substrates W (step S1). The nitrogen-containing gas is not limited to the NH₃ gas, and may be, for example, N₂ gas.

Then, the control device 90 performs the vacuum purge step by supplying an inert gas such as Ar gas from the injectors 14 and 15, and exhausting the inside of the reaction tube 3 by the exhaust device 31 (step S3).

Then, the control device 90 causes the SiH₂Cl₂ gas to flow in the reaction tube 3 from the injector 14, to cause a thermal reaction (step S5). At this time, plasma is not used. Thus, the substrates W are exposed to the film formation gas containing silicon, to form the SiN film. Then, the control device 90 performs the vacuum purge step by supplying an inert gas such as Ar gas from the injectors 14 and 15, and exhausting the inside of the reaction tube 3 by the exhaust device 31 (step S7).

Then, the control device 90 supplies the direct current to the coils 61 and 62, to generate the magnetic fields in the plasma generation portion 60. Further, the H₂ gas is supplied from the injector 15, and the radio-frequency power is applied to the radio-frequency electrodes 26. As a result, plasma is generated from the H₂ gas by the radio-frequency power, and the substrates W are exposed to the generated plasma of the H₂ gas (step S9). Accordingly, the hydrogen radical purge (HRP) step is performed. Thus, the stress occurring in the formed SiN film is controlled. As a result, the particles generated on the substrates W may be reduced by controlling the stress in the film.

Then, the control device 90 performs the vacuum purge step by supplying an inert gas such as Ar gas from the injectors 14 and 15, and exhausting the inside of the reaction tube 3 by the exhaust device 31 (step S11). Step S11 may be omitted.

Then, the control device 90 determines whether the process has been repeated a predetermined number of times (step S13). When it is determined that the process has not been repeated a predetermined number of times, the control device 90 returns to step S1, and repeats steps S1 to S11 in this order. When it is determined in step S13 that the process has been repeated a predetermined number of times, the control device 90 ends the process.

According to the film forming method of the present embodiment, plasma is generated in steps S1 and S9. At this time, the radio-frequency power is supplied to the radio-frequency electrodes 26 provided in the electrode installation portions 70 disposed along the plasma generation portion 60, and the direct current is supplied to the coils 61 and 62 provided in the electrode installation portions 70.

As a result, the time for step S1 (nitriding time) may be reduced by about 10% to about 20%, and the time for step S9 (HRP time) may be reduced by about 10% to 30%, while maintaining the film forming performance. The film forming performance refers to the film quality, the uniformity of film thickness, and the rate of the ALD cycle (thickness of the film produced in one cycle of steps S1 to S11).

In the present embodiment, the thermal processing apparatus 1 provided with the coils 61 and 62 is used. As a result, the time for the dry cleaning cycle may be extended up to about 1.5 times, as compared with a thermal processing apparatus in which the coils 61 and 62 are not provided. As a result, the operation rate of the thermal processing apparatus 1 may be improved. The man-hours or material costs for the quality assurance may be reduced.

As described above, according to the plasma processing apparatus and the film forming method of the present disclosure, the density of plasma generated by the plasma generation portion 60 may be increased. Further, in the film forming method, the productivity may be improved while suppressing the generation of particles. The time for the nitriding by the plasma of the NH₃ gas and the time for the HRP by the plasma of the H₂ gas may be reduced, for example, within the range of the time of the film formation recipe (ALD cycle time) used for the film forming method of the present embodiment by the ALD method. As a result, while improving the productivity, the generation of particles may be suppressed by optimizing the stress occurring in the formed SiN film. Thus, the dry cleaning cycle may be extended up to about 1.5 times the current cycle.

Without being limited to the formation of the SiN film, the film forming method of the present embodiment may be used for other film formations. Further, for example, the film forming method of the present embodiment may also be used for processing the surface of a desired film, to change the surface state of the film. For example, when the substrates W on which a silicon oxide film (SiO₂) is formed are carried into a plasma processing apparatus to generate the plasma of the NH₃ gas, and the substrates W are processed with the plasma, the surface of the silicon oxide film is nitrided. According to the plasma processing apparatus of the present embodiment, the density of the plasma of the NH₃ gas may be increased, and as a result, the time for the surface processing may be reduced.

According to an aspect of the present disclosure, the plasma density may be increased.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a reaction tube provided in a processing container;
a boat configured to hold a substrate and be carried into and out from the reaction tube in order to form a film on the substrate;
a plasma generation tube communicating with the reaction tube, and configured to generate plasma from a gas;
a gas supply configured to supply the gas to the plasma generation tube;
electrode installation columns provided to sandwich the plasma generation tube therebetween, and including electrodes, respectively;
an RF power supply connected to the electrodes, and configured to supply a radio frequency to the electrodes;
a coil provided to be spaced apart from the electrodes in the electrode installation columns; and
a DC power supply connected to the coil, and configured to supply a direct current to the coil.

2. The plasma processing apparatus according to claim 1, wherein the plasma generation tube protrudes from the reaction tube in a rectangular shape, and
the electrode installation columns are provided along plasma partition walls of the plasma generation tube protruding in the rectangular shape.

3. The plasma processing apparatus according to claim 2, wherein the coil is wound one or more times along the plasma partition walls of the plasma generation tube.

4. The plasma processing apparatus according to claim 1, wherein the electrodes are provided to face each other in the electrode installation columns, and
one or more coils are provided side by side with the electrodes.

5. The plasma processing apparatus according to claim 1, wherein the electrodes are provided to face each other in the electrode installation columns, and
a plurality of coils is provided on both sides of the electrodes.

6. The plasma processing apparatus according to claim 4, wherein at least one of the coils is provided closer to the reaction tube than the electrodes.

7. A film forming method for forming a film on a substrate in the plasma processing apparatus according to claim 1, the method comprising:
(a) exposing the substrate to plasma generated from a nitrogen-containing gas;
(b) exposing the substrate to a film formation gas containing silicon;
(c) exposing the substrate to plasma formed from hydrogen gas; and
(d) repeating (a) to (c) in this order,
wherein when the plasma is generated in (a) and (c), a radio frequency is supplied to the electrodes provided in the electrode installation columns arranged along the plasma generation tube, and a direct current is supplied to the coil provided in the electrode installation columns.

8. The film forming method according to claim 7, further comprising purging an inside of the reaction tube between (a) and (b), and between (b) and (c).
